(19) United States
(12) Patent Application Publication
(10) Pub. No.: US 2024/0122023 A1
(43) Pub. Date: Apr. 11, 2024

(54) DISPLAY APPARATUS

(71) Applicant: Samsung Display Co., LTD., Yongi-si (KR)

(72) Inventors: Jinsu LEE, Yongin-si (KR); Hyunduck CHO, Yongin-si (KR); Hongjo PARK, Yongin-si (KR); Beohmrock CHOI, Yongin-si (KR)

(21) Appl. No.: 18/375,481

(22) Filed: Sep. 30, 2023

(30) Foreign Application Priority Data
Oct. 7, 2022 (KR) 10-2022-0129033

(51) Int. Cl. H10K 59/38; H10K 59/122; H10K 59/126; H10K 59/35

(52) U.S. Cl. CPC H10K 59/38; H10K 59/122; H10K 59/126; H10K 59/352; H10K 59/353

(57) ABSTRACT

A display apparatus includes a substrate, a plurality of subpixels disposed over the substrate and including a red subpixel, a blue subpixel, and a green subpixel, an encapsulation layer over the plurality of subpixels, a light-blocking layer disposed over the encapsulation layer and including a plurality of openings respectively overlapping the plurality of subpixels, and a plurality of color filters disposed over the light-blocking layer and including a red color filter, a blue color filter, and a green color filter. The plurality of color filters include a repetitive arrangement structure of a color filter pattern unit block, the plurality of subpixels include a repetitive arrangement structure of a subpixel pattern unit block, and a size of the color filter pattern unit block is greater than a size of the subpixel pattern unit block.

This application claims priority to Korean Patent Application No. 10-2022-0129033, filed on Oct. 7, 2022, and all the benefits accruing therefrom under 35 U.S.C. § 119, the content of which in its entirety is herein incorporated by reference.

### BACKGROUND

### 1. Field

Embodiments relate to display apparatuses.

### 2. Description of the Related Art

Display apparatuses may visually display data. A display apparatus may be used as a display unit of a small product such as a mobile phone or may be used as a display unit of a large product such as a television.

A display apparatus may include a plurality of subpixels that receive an electrical signal to emit light to display an image to the outside. Each subpixel may include a light-emitting device and may include an organic light-emitting diode (“OLED”) as a light-emitting device in a case of an organic light-emitting display apparatus, for example. Generally, in the organic light-emitting display apparatus, thin film transistors and organic light-emitting diodes are formed over a substrate and the organic light-emitting diodes emit light and operate by themselves.

Recently, as a use of display apparatuses is being diversified, various designs are being attempted to improve the quality of display apparatuses.

### SUMMARY

Embodiments include a display apparatus in which the design of a color filter for adjusting the reflection color is easily modified. However, these problems are merely examples and the scope of the disclosure is not limited thereto.

Additional features will be set forth in part in the description which follows and, in part, will be apparent from the description, or may be learned by practice of the presented embodiments of the disclosure.

In an embodiment of the disclosure, a display apparatus includes a substrate, a plurality of subpixels including a red subpixel, a blue subpixel, and a green subpixel each including a subpixel electrode, an emission layer over the subpixel electrode, and an opposite electrode over the emission layer, an encapsulation layer over the plurality of subpixels, a light-blocking layer disposed over the encapsulation layer and including a plurality of openings respectively overlapping the plurality of subpixels, and a plurality of color filters disposed over the light-blocking layer and including a red color filter, a blue color filter, and a green color filter. The plurality of color filters includes a repetitive arrangement structure of a color filter pattern unit block including the red color filter, the blue color filter, and the green color filter, the plurality of subpixels includes a repetitive arrangement structure of a subpixel pattern unit block including the red subpixel, the blue subpixel, and the green subpixel, and a size of the color filter pattern unit block is greater than a size of the subpixel pattern unit block.

In an embodiment, each of the red subpixel, the green subpixel and the blue subpixel may be provided in plural, and in the subpixel pattern unit block, a number of green subpixels may be equal to a sum of a number of red subpixels and a number of blue subpixels.

In an embodiment, the plurality of subpixels may be arranged in a Pentile structure.

In an embodiment, subpixels of the plurality of subpixels corresponding to the color filter pattern unit block may have a structure in which K (K is a natural number) subpixel pattern unit blocks are arranged in a first direction and L (L is a natural number) subpixel pattern unit blocks are arranged in a second direction orthogonal to the first direction.

In an embodiment, the plurality of color filters may include a plurality of first sub color filters respectively arranged in a plurality of first areas, filling at least a portion of openings of the light-blocking layer, and including a first red sub color filter, a first blue sub color filter, and a first green sub color filter, and a plurality of second sub color filters respectively arranged in a plurality of second areas between the plurality of first areas, covering an upper surface of the light-blocking layer, and including a second red sub color filter, a second blue sub color filter, and a second green sub color filter.

In an embodiment, the plurality of second areas may have a same size.

In an embodiment, a color filter of the plurality of color filters may not be disposed in at least one of the plurality of second areas.

In an embodiment, among the plurality of first sub color filters and the plurality of second sub color filters, color filters contacting each other and having a same color may be unitary with each other.

In an embodiment, the color filter pattern unit block may include a first sub color filter pattern in which the plurality of first sub color filters is arranged and a second sub color filter pattern in which the plurality of second sub color filters is arranged.

In an embodiment, in the second sub color filter pattern, second sub color filters of two or more colors among the plurality of the second sub color filters may be arranged in at least one of a first direction and a second direction orthogonal to the first direction.

In an embodiment, in the second sub color filter pattern, the second sub color filters of two or more colors among the plurality of the second sub color filters may be arranged in a diagonal direction oblique to a first direction and a second direction orthogonal to the first direction.

In an embodiment, a size of the first red sub color filter may be less than a size of the first blue sub color filter and a size of the first green sub color filter.

In an embodiment, the plurality of first sub color filters may have a circular shape in a plan view.

In an embodiment, a first sub color filter of the plurality of first sub color filters and a second sub color filter of the plurality of second sub color filters adjacent to each other may contact or overlap each other over the light-blocking layer.

In an embodiment, the plurality of color filters may include a first color filter pattern unit including the red color filter, the blue color filter, and the green color filter, and the color filter pattern unit block may have a same size as or a greater size than a size of the first color filter pattern unit.

In an embodiment, the color filter pattern unit block may include the first color filter pattern unit and a second color filter pattern unit adjacent to the first color filter pattern unit and including the red color filter, the blue color filter, and the green color filter, and each of the first color filter pattern unit and the second color filter pattern unit may include first sub color filters of the plurality of first sub color filters and second sub color filters of the plurality of second sub color filters. An arrangement of the second sub color filters of the second color filter pattern unit may be different from an arrangement of the second sub color filters of the first color filter pattern unit.

In an embodiment, a number of second red sub color filters included in the second color filter pattern unit may be equal to a number of second red sub color filters included in the first color filter pattern unit, a number of second blue sub color filters included in the second color filter pattern unit may be equal to a number of second blue sub color filters included in the first color filter pattern unit, and a number of second green sub color filters included in the second color filter pattern unit may be equal to a number of second green sub color filters included in the first color filter pattern unit.

In an embodiment, the display apparatus may further include a bank layer in which a plurality of subpixel openings exposing at least a portion of each of the plurality of subpixel electrodes is defined, and a touch sensor layer including touch electrodes arranged between the encapsulation layer and the light-blocking layer. The touch electrodes may overlap the bank layer and some of the plurality of color filters.

In an embodiment, at least one of the touch electrodes may directly contact the light-blocking layer.

In an embodiment, the bank layer may include a light-blocking material.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a perspective view schematically illustrating an embodiment of a display apparatus;

FIG. 2 is a cross-sectional view schematically illustrating an embodiment of a display apparatus, taken along line A-A′ of FIG. 1;

FIG. 3 is a cross-sectional view schematically illustrating an embodiment of a display apparatus;

FIG. 4 is a plan view illustrating an embodiment of an arrangement of subpixels of a portion of a display apparatus;

FIG. 5 is a plan view illustrating an embodiment of a portion of a display apparatus;

FIG. 6 is a cross-sectional view of the display apparatus taken along line B-B′ of FIG. 5;

FIG. 7 is a cross-sectional view of the display apparatus taken along line C-C′ of FIG. 5;

FIG. 8 is a plan view illustrating an embodiment of a portion of a display apparatus;

FIG. 9 is a plan view illustrating an embodiment of a color filter pattern unit block in FIG. 8;

FIG. 10 is a plan view illustrating another embodiment of a portion of a display apparatus; and

FIG. 11 is a plan view illustrating another embodiment of a portion of a display apparatus.

### DETAILED DESCRIPTION

Reference will now be made in detail to embodiments, illustrative embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may include various embodiments and modifications, and illustrative embodiments thereof are illustrated in the drawings and will be described herein in detail. The effects and features of the disclosure and the accomplishing methods thereof will become apparent from the embodiments described below in detail with reference to the accompanying drawings. However, the disclosure is not limited to the embodiments described below and may be embodied in various modes.

It will be understood that although terms such as “first” and “second” may be used herein to describe various elements, these elements should not be limited by these terms and these terms are only used to distinguish one element from another element.

As used herein, the singular forms “a,” “an,” and “the” are intended to include the plural forms as well, unless the context clearly indicates otherwise.

It will be understood that terms such as “comprise,” “include,” and “have” used herein specify the presence of stated features or elements, but do not preclude the presence or addition of one or more other features or elements.

It will be understood that when a layer, region, area, component, or element is also referred to as being “on” another layer, region, area, component, or element, it may be “directly on” the other layer, region, area, component, or element or may be “indirectly on” the other layer, region, area, component, or element with one or more intervening layers, regions, areas, components, or elements therebetween.

Sizes of elements in the drawings may be exaggerated for convenience of description. In other words, because the sizes and thicknesses of elements in the drawings are arbitrarily illustrated for convenience of description, the disclosure is not limited thereto.

As used herein, “A and/or B” represents the case of A, B, or A and B. Also, “at least one of A and B” represents the case of A, B, or A and B.

In the following embodiments, the meaning of a line “extending in a first direction or a second direction” may include not only extending in a linear shape but also extending in a zigzag or curved shape in the first direction or the second direction.

In the following embodiments, when referred to as “in a plan view,” it may mean that a target portion is viewed from above, and when referred to as “in a cross-sectional view,” it may mean that a cross-section of a target portion vertically cut is viewed from side. In the following embodiments, when referred to as “overlapping,” it may include overlapping “in a plan view” and overlapping “in a cross-sectional view.”

Hereinafter, embodiments will be described in detail with reference to the accompanying drawings, and in the following description, like reference numerals will denote like elements.

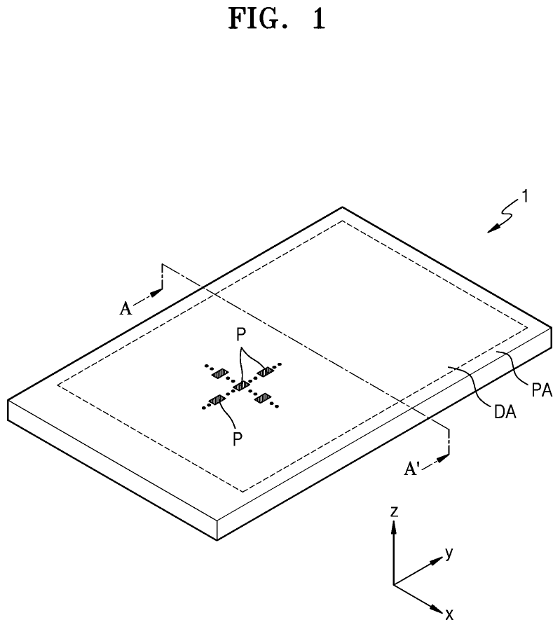

Referring to FIG. 1, a display apparatus 1 may include a display area DA and a peripheral area PA outside the display area DA. The display apparatus 1 may provide an image through an array of a plurality of subpixels P two-dimensionally arranged in the display area DA.

Each subpixel P of the display apparatus 1 may be an area capable of emitting light of a predetermined color, and the display apparatus 1 may provide an image by light emitted from the subpixels P. In an embodiment, each subpixel P may emit red, green, blue, or white light, for example.

Each of the subpixels P may emit light of a predetermined color by a light-emitting diode, e.g., an organic light-emitting diode. Each organic light-emitting diode may emit, e.g., red, green, blue, or white light. Each organic light-emitting diode may be connected to a subpixel circuit including a thin film transistor and a capacitor.

The peripheral area PA may be an area not providing an image and may surround an entirety of the display area DA. A driver or a main power line for providing an electrical signal or power to subpixel circuits may be disposed in the peripheral area PA. The peripheral area PA may include a pad that is an area to which an electronic device or a printed circuit board may be electrically connected.

The display area DA may have a polygonal shape including a tetragonal shape as illustrated in FIG. 1. In an embodiment, the display area DA may have a quadrangular (e.g., rectangular) shape in which the horizontal length is greater than the vertical length, may have a quadrangular (e.g., rectangular) shape in which the horizontal length is less than the vertical length, or may have a square shape. In an alternative embodiment, the display area DA may have various shapes such as an elliptical shape or a circular shape.

The electronic apparatus 1 may include a mobile phone, a television, a billboard, a tablet personal computer (“PC”), a notebook, a smart band, or a smart watch worn on the wrist.

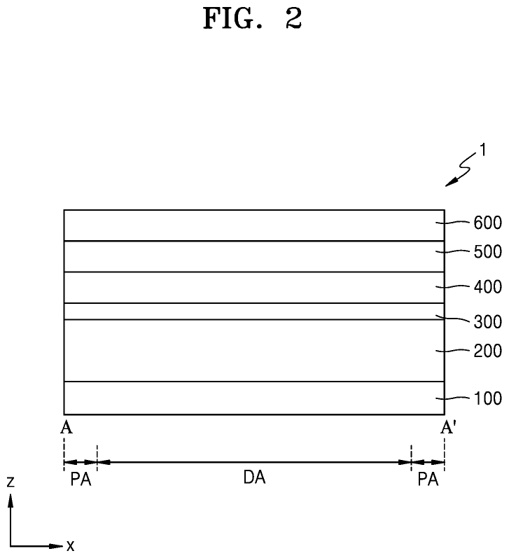

FIG. 2 is a cross-sectional view schematically illustrating an embodiment of a display apparatus, taken along line A-A′ of FIG. 1.

Referring to FIG. 2, the display apparatus 1 in an embodiment may include a substrate 100, a display layer 200, a low-reflection layer 300, an encapsulation layer 400, a touch sensor layer 500, and an anti-reflection layer 600.

The substrate 100 may include glass or polymer resin. In an embodiment, the polymer resin may include polyether sulfone, polyacrylate, polyether imide, polyethylene naphthalate, polyethylene terephthalate, polyphenylene sulfide, polyarylate, polyimide, polycarbonate, or cellulose acetate propionate, for example. The substrate 100 including the polymer resin may be flexible, rollable, or bendable. The substrate 100 may have a multilayer structure including an inorganic layer (not illustrated) and a layer including the polymer resin.

The display layer 200 may include an organic light-emitting diode as a display element, a thin film transistor electrically connected to the organic light-emitting diode, and insulating layers arranged therebetween.

The low-reflection layer 300 may be disposed over the display layer 200, and the encapsulation layer 400 may be disposed over the low-reflection layer 300. In an embodiment, the display layer 200 and/or the low-reflection layer 300 may be encapsulated by the encapsulation layer 400, for example. In some embodiments, the low-reflection layer 300 may be omitted. In this case, the encapsulation layer 400 may be directly disposed over the display layer 200. The encapsulation layer 400 may include at least one inorganic layer and at least one organic layer.

In some embodiments, an encapsulation substrate (not illustrated) including a glass material may be provided instead of the encapsulation layer 400. The encapsulation substrate may be disposed over the display layer 200, and the display layer 200 may be arranged between the substrate 100 and the encapsulation substrate. There may be a gap between the encapsulation substrate and the display layer 200, and the gap may be filled with a filler.

The touch sensor layer 500 may be disposed over the encapsulation layer 400. The touch sensor layer 500 may sense an external input, e.g., a touch of an object such as a finger or a stylus pen, such that the display apparatus 1 may obtain coordinate information corresponding to a touch position. The touch sensor layer 500 may include a touch electrode and trace lines connected to the touch electrode. The touch sensor layer 500 may sense an external input by a mutual cap method or a self-cap method.

In an embodiment, the touch sensor layer 500 may be directly formed over the encapsulation layer 400. In an alternative embodiment, the touch sensor layer 500 may be separately formed and then adhered onto the encapsulation layer 400 through an adhesive layer such as optically clear adhesive (“OCA”).

The anti-reflection layer 600 may be disposed over the touch sensor layer 500. The anti-reflection layer 600 may reduce the reflectance of light (external light) incident from the outside toward the display apparatus 1.

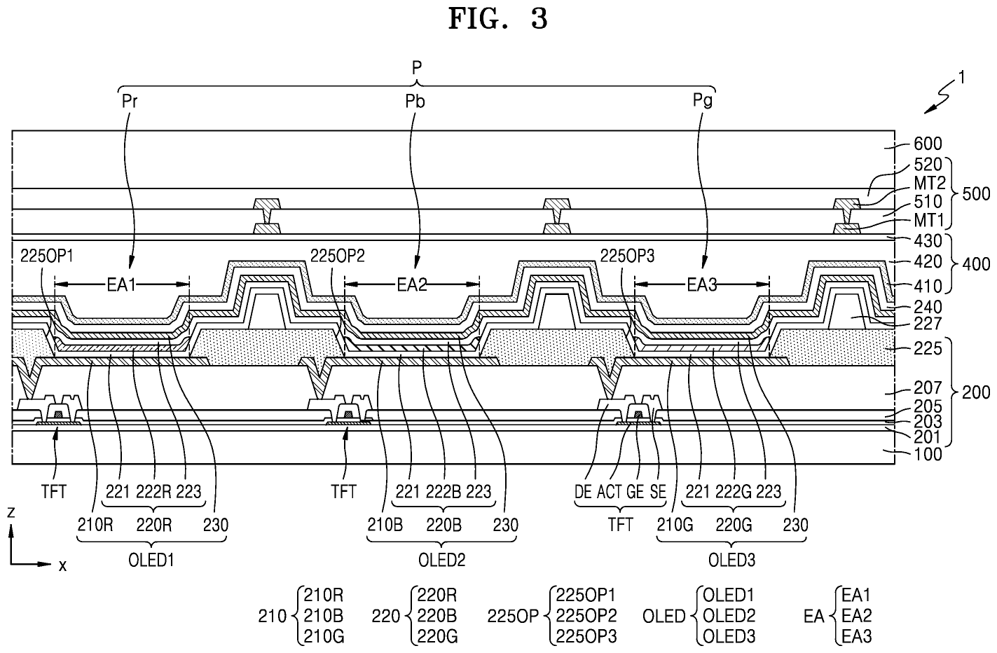

FIG. 3 is a cross-sectional view schematically illustrating an embodiment of a portion of a display apparatus. Hereinafter, a stack structure of the display apparatus 1 is described in more detail with reference to FIG. 3.

Referring to FIG. 3, the display apparatus 1 may include a substrate 100, a display layer 200, an encapsulation layer 400, a touch sensor layer 500, and an anti-reflection layer 600.

The display layer 200 may be disposed over the substrate 100. The display layer 200 may include a subpixel circuit layer and a light-emitting diode layer. The subpixel circuit layer may include a thin film transistor TFT and may include a buffer layer 201, a gate insulating layer 203, an inter-insulating layer 205, and a planarization layer 207 that are insulating layers.

The buffer layer 201 may be disposed over the substrate 100 to reduce or block the penetration of foreign materials, moisture, or external air from under the substrate 100 and may provide a flat surface over the substrate 100. The buffer layer 201 may include an inorganic material such as oxide or nitride, an organic material, or an organic/inorganic composite and may include a single-layer or multiple-layer structure of an inorganic material and an organic material. A barrier layer (not illustrated) for blocking the penetration of external air may be further included between the substrate 100 and the buffer layer 201. In an embodiment, the buffer layer 201 may include silicon oxide or silicon nitride, for example.

The thin film transistor TFT may be disposed over the buffer layer 201. The thin film transistor TFT may include a semiconductor layer ACT, a gate electrode GE, a source electrode SE, and a drain electrode DE. The thin film transistor TFT may be connected to an organic light-emitting diode OLED to drive the organic light-emitting diode OLED.

The semiconductor layer ACT may be disposed over the buffer layer 201. The semiconductor layer ACT may include polysilicon or amorphous silicon. In an alternative embodiment, the semiconductor layer ACT may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), and zinc (Zn). The semiconductor layer ACT may include a channel area, and a source area and a drain area that are doped with dopants.

The gate electrode GE, the source electrode SE, and the drain electrode DE may include or consist of various conductive materials. In an embodiment, the gate electrode GE may include at least one of molybdenum (Mo), aluminum (Al), copper (Cu), and titanium (Ti). In an embodiment, the gate electrode GE may include a single molybdenum (Mo) layer or may include a three-layer structure including a molybdenum (Mo) layer, an aluminum (Al) layer, and a molybdenum (Mo) layer, for example. In an embodiment, the source electrode SE and the drain electrode DE may include at least one of copper (Cu), titanium (Ti), and aluminum (Al). In an embodiment, the source electrode SE and the drain electrode DE may include a three-layer structure including a titanium (Ti) layer, an aluminum (Al) layer, and a titanium (Ti) layer, for example.

Moreover, in order to secure the insulation between the semiconductor layer ACT and the gate electrode GE, the gate insulating layer 203 may be arranged between the semiconductor layer ACT and the gate electrode GE. The inter-insulating layer 205 may be disposed over the gate electrode GE, and the source electrode SE and the drain electrode DE may be disposed over the inter-insulating layer 205.

Each of the gate insulating layer 203 and the inter-insulating layer 205 may include an inorganic material such as silicon oxide, silicon nitride, and/or silicon oxynitride. The gate insulating layer 203 and the inter-insulating layer 205 may include an insulating layer including an inorganic material may be formed through chemical vapor deposition (“CVD”) or atomic layer deposition (“ALD”). This may also be similarly applied to embodiments described below.

The planarization layer 207 may be disposed over the thin film transistor TFT. In order to provide a flat upper surface, chemical mechanical polishing may be performed on the upper surface of the planarization layer 207 after the planarization layer 207 is formed. The planarization layer 207 may include a general-purpose polymer such as photosensitive polyimide, polyimide, polystyrene (“PS”), polycarbonate (“PC”), benzocyclobutene (“BCB”), hexamethyldisiloxane (“HMDSO”), or polymethylmethacrylate (“PMMA”), a polymer derivative having a phenolic group, an acrylic polymer, an imide-based polymer, an aryl ether-based polymer, an amide-based polymer, a fluorine-based polymer, a p-xylene-based polymer, or a vinyl alcohol-based polymer. FIG. 3 illustrates that the planarization layer 207 includes a single layer; however, in some embodiments, the planarization layer 207 may include multiple layers. A subpixel electrode 210 of the organic light-emitting diode OLED may be directly connected to the thin film transistor TFT through a contact hole of the planarization layer 207.

The light-emitting diode layer may be disposed over the subpixel circuit layer. The light-emitting diode layer may include a light-emitting diode. In an embodiment, the light-emitting diode layer may include first to third organic light-emitting diodes OLED1, OLED2, and OLED3, a bank layer 225, and a spacer 227.

The first to third organic light-emitting diodes OLED1, OLED2, and OLED3 may be disposed over the subpixel circuit layer. The first organic light-emitting diode OLED1 may include a stack structure of a first subpixel electrode 210R, a first intermediate layer 220R including a first common layer 221, a first emission layer 222R, and a second common layer 223, and an opposite electrode 230, the second organic light-emitting diode OLED2 may include a second subpixel electrode 210B, a second intermediate layer 220B including a first common layer 221, a second emission layer 222B, and a second common layer 223, and an opposite electrode 230, and the third organic light-emitting diode OLED3 may include a third subpixel electrode 210G, a third intermediate layer 220G including a first common layer 221, a third emission layer 222G, and a second common layer 223, and an opposite electrode 230.

Hereinafter, the first organic light-emitting diode OLED1 included in the first subpixel will be described as a representative, and because the stack structure of the second organic light-emitting diode OLED2 and the third organic light-emitting diode OLED3 is substantially the same as the stack structure of the first organic light-emitting diode OLED1, redundant descriptions thereof are omitted for conciseness.

The organic light-emitting diode OLED may include a subpixel electrode 210, an intermediate layer 220, and an opposite electrode 230.

The subpixel electrode 210 may be disposed over the planarization layer 207. The subpixel electrode 210 may be disposed in each subpixel. The subpixel electrodes 210 respectively corresponding to the subpixels may be arranged apart from each other.

The subpixel electrode 210 may be a reflective electrode. The subpixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any combinations thereof, and a transparent or semitransparent conductive layer formed over the reflective layer. The transparent or semitransparent conductive layer may include at least one of indium tin oxide (“ITO”), indium zinc oxide (“IZO”), zinc oxide (ZnO), indium oxide (In₂O₃), indium gallium oxide (“IGO”), and aluminum zinc oxide (“AZO”).

The bank layer 225 may be disposed over the subpixel electrodes 210. First to third subpixel openings 225OP1, 225OP2, and 2225OP3 overlapping the subpixel electrode 210 and exposing a center portion of the subpixel electrode 210 may be defined in the bank layer 225. The bank layer 225 may cover the edge of the subpixel electrode 210 and increase the distance between the edge of the subpixel electrode 210 and the opposite electrode 230 to prevent an arc or the like from occurring at the edge of the subpixel electrode 210.

The first to third subpixel openings 225OP1, 225OP2, and 225OP3 of the bank layer 225 may define first to third emission areas EA1, EA2, and EA3 of the first to third organic light-emitting diodes OLED1, OLED2, and OLED3 included in the respective subpixels P. As illustrated in FIG. 3, the first subpixel opening 225OP1 defining the first emission area EA1 of the first organic light-emitting diode OLED1 of the first subpixel may be defined in the bank layer 225. Also, the second subpixel opening 225OP2 defining the second emission area EA2 of the second organic light-emitting diode OLED2 of the second subpixel and the third subpixel opening 225OP3 defining the third emission area EA3 of the third organic light-emitting diode OLED3 of the third subpixel may be defined in the bank layer 225.

The bank layer 225 may include an organic insulating material. In an alternative embodiment, the bank layer 225 may include an inorganic insulating material such as silicon nitride or silicon oxide. In some embodiments, the bank layer 225 may include an organic insulating material and an inorganic insulating material.

The bank layer 225 may include a light-blocking material. In an embodiment, the light-blocking material of the bank layer 225 may be black, for example. The light-blocking material may include a resin or paste including carbon black, carbon nanotube, or black dye, metal particles (e.g., nickel, aluminum, molybdenum, or any alloy thereof), metal oxide particles, or metal nitride particles. When the bank layer 225 includes a light-blocking material, the reflection of external light by metal structures disposed under the bank layer 225 may be reduced. However, the disclosure is not limited thereto. In another embodiment, the bank layer 225 may include a transparent organic insulating material instead of including the light-blocking material.

The spacer 227 may be disposed over the bank layer 225. The spacer 227 may include an organic insulating material such as polyimide. In an alternative embodiment, the spacer 227 may include an inorganic insulating material such as silicon nitride or silicon oxide or may include an organic insulating material and an inorganic insulating material. The spacer 227 may include a different material from that of the bank layer 225 including the above light-blocking material and may be formed in a separate process from the bank layer 225.

In another embodiment, the spacer 227 may include the same material as that of the bank layer 225. In this case, the bank layer 225 and the spacer 227 may be formed together in a mask process using a halftone mask.

The intermediate layer 220 may be disposed over the subpixel electrode 210 and the bank layer 225. The intermediate layer 220 may include a first common layer 221, an emission layer (i.e., the first emission layer 222R), and a second common layer 223.

The emission layer may be disposed inside the first to third subpixel openings 225OP1, 225OP2, and 225OP3 of the bank layer 225. The emission layer may include an organic material including a fluorescent or phosphorescent material capable of emitting blue, green, or red light. The above organic material layer may include a low-molecular weight organic material or a high-molecular weight organic material.

The first common layer 221 and the second common layer 223 may be respectively disposed under and over the emission layer. The first common layer 221 may include, e.g., a hole transport layer (“HTL”) or may include an HTL and a hole injection layer (“HIL”). The second common layer 223 may include, e.g., an electron transport layer (“ETL”) or may include an ETL and an electron injection layer (“EIL”). In an embodiment, the second common layer 223 may be omitted.

The emission layer may be disposed in each subpixel P to correspond to the first to third subpixel openings 225OP1, 225OP2, and 225OP3 of the bank layer 225, whereas each of the first common layer 221 and the second common layer 223 may be unitary to cover an entirety of the substrate 100. In other words, each of the first common layer 221 and the second common layer 223 may be unitary to cover an entirety of the display area DA of the substrate 100.

The opposite electrode 230 may be a cathode that is an electron injection electrode. The opposite electrode 230 may include a conductive material having a substantially low work function. In an embodiment, the opposite electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. In an alternative embodiment, the opposite electrode 230 may further include a layer such as ITO, IZO, ZnO, or In₂O₃ over the (semi)transparent layer including the above material.

In an embodiment, a capping layer 240 may be further disposed over the display layer 200. The capping layer 240 may be disposed over the first to third organic light-emitting diodes OLED1, OLED2, and OLED3. In an embodiment, the capping layer 240 may improve the light emission efficiency of the first to third organic light-emitting diodes OLED1, OLED2, and OLED3 by the principle of constructive interference.

The capping layer 240 may be an organic capping layer including an organic material, an inorganic capping layer including an inorganic material, or a composite capping layer including an organic material and an inorganic material. In an embodiment, the capping layer 240 may include a carbocyclic compound, a heterocyclic compound, an amine group-containing compound, a porphine derivative, a phthalocyanine derivative, a naphthalocyanine derivative, an alkali metal complex, an alkaline earth metal complex, or any combinations thereof. The carbocyclic compound, the heterocyclic compound, and the amine group-containing compound may be selectively substituted with a substituent including O, N, S, Se, Si, F, Cl, Br, I, or any combinations thereof.

The encapsulation layer 400 may be disposed over the capping layer 240. The encapsulation layer 400 may include at least one inorganic layer and at least one organic layer. In an embodiment, as illustrated in FIG. 3, the encapsulation layer 400 may include a first inorganic encapsulation layer 410, an organic encapsulation layer 420, and a second inorganic encapsulation layer 430 that are sequentially stacked, for example.

The first inorganic encapsulation layer 410 and the second inorganic encapsulation layer 430 may include an inorganic insulating material such as silicon oxide, silicon nitride, silicon oxynitride, aluminum oxide, titanium oxide, tantalum oxide, hafnium oxide, or zinc oxide. The first inorganic encapsulation layer 410 and the second inorganic encapsulation layer 430 may have a single-layer or multiple-layer structure including the above inorganic insulating material.

The organic encapsulation layer 420 may relieve the internal stress of the first inorganic encapsulation layer 410 and/or the second inorganic encapsulation layer 430. The organic encapsulation layer 420 may include a polymer-based material. In an embodiment, the organic encapsulation layer 420 may include polyethyleneterephthalate, polyethylenenaphthalate, polycarbonate, polyimide, polyethylenesulfonate, polyoxymethylene, polyarylate, hexamethyldisiloxane, acrylic resin (e.g., polymethylmethacrylate or polyacrylic acid), or any combinations thereof, for example.

The encapsulation layer 400 may have a multilayer structure of the first inorganic encapsulation layer 410, the organic encapsulation layer 420, and the second inorganic encapsulation layer 430. In this case, even when a crack occurs in the encapsulation layer 400, the crack may not propagate between the first inorganic encapsulation layer 410 and the organic encapsulation layer 420 or between the organic encapsulation layer 420 and the second inorganic encapsulation layer 430. The encapsulation layer 400 may prevent or minimize the penetration of external moisture or oxygen into the display area DA.

The touch sensor layer 500 may be disposed over the encapsulation layer 400. The touch sensor layer 500 may include a first touch electrode MT1, a first touch insulating layer 510, a second touch electrode MT2, and a second touch insulating layer 520. The first touch electrode MT1 may be directly disposed over the encapsulation layer 400. In an embodiment, the first touch electrode MT1 may be directly disposed over the second inorganic encapsulation layer 430 of the encapsulation layer 400, for example. However, the disclosure is not limited thereto.

In an embodiment, the touch sensor layer 500 may include an insulating layer (not illustrated) disposed between the first touch electrode MT1 and the encapsulation layer 400. In this case, the insulating layer may be disposed over the second inorganic encapsulation layer 430 of the encapsulation layer 400 to planarize a surface on which the first touch electrode MT1 or the like is disposed. The insulating layer may include an inorganic insulating material such as silicon oxide, silicon nitride, or silicon oxynitride. In some embodiments, the insulating layer may include an organic insulating material.

The first touch insulating layer 510 may be disposed over the first touch electrode MT1. The first touch insulating layer 510 may include an inorganic material or an organic material. When the first touch insulating layer 510 includes an inorganic material, the first touch insulating layer 510 may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. When the first touch insulating layer 510 includes an organic material, the first touch insulating layer 510 may include at least one of acryl-based resin, methacryl-based resin, polyisoprene, vinyl-based resin, epoxy-based resin, urethane-based resin, cellulose-based resin, and perylene-based resin.

The second touch electrode MT2 may be disposed over the first touch insulating layer 510. The second touch electrode MT2 may function as a sensor for sensing a user's touch input. The first touch electrode MT1 may function as a connector for connecting the second touch electrode MT2 patterned, in one direction. In an embodiment, both the first touch electrode MT1 and the second touch electrode MT2 may function as a sensor. In this case, the first touch electrode MT1 and the second touch electrode MT2 may be electrically connected through a contact hole. When both the first touch electrode MT1 and the second touch electrode MT2 function as a sensor, the resistance of the touch electrodes may decrease and thus a user's touch input may be rapidly sensed.

In an embodiment, the first touch electrode MT1 and the second touch electrode MT2 may have a structure through which light emitted from the organic light-emitting diode OLED may pass a mesh structure, for example. In this case, the first touch electrode MT1 and the second touch electrode MT2 may be arranged not to overlap an emission area EA of the organic light-emitting diode OLED.

The first touch electrode MT1 and the second touch electrode MT2 may include a metal layer or a transparent conductive layer. The metal layer may include molybdenum (Mo), silver (Ag), titanium (Ti), copper (Cu), aluminum (Al), or any alloy thereof. The transparent conductive layer may include a transparent conductive oxide such as indium tin oxide (“ITO”), indium zinc oxide (“IZO”), zinc oxide (ZnO), or indium tin zinc oxide (“ITZO”), a conductive polymer such as PEDOT, a metal nanowire, a carbon nanotube, or graphene.

The second touch insulating layer 520 may be disposed over the second touch electrode MT2. The second touch insulating layer 520 may include an inorganic material or an organic material. When the second touch insulating layer 520 includes an inorganic material, the second touch insulating layer 520 may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. When the second touch insulating layer 520 includes an organic material, the second touch insulating layer 520 may include at least one of acryl-based resin, methacryl-based resin, polyisoprene, vinyl-based resin, epoxy-based resin, urethane-based resin, cellulose-based resin, and perylene-based resin.

In some embodiments, the touch sensor layer 500 may include the first touch electrode MT1, the first touch insulating layer 510, and the second touch electrode MT2 and may not include the second touch insulating layer 520. In this case, the anti-reflection layer 600 may be provided to cover the second touch electrode MT2.

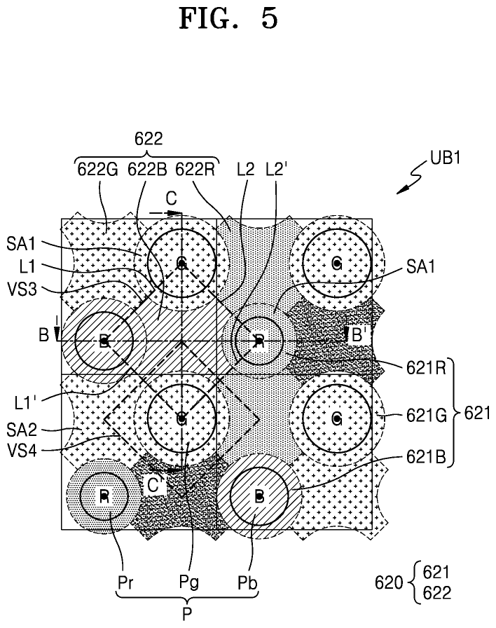

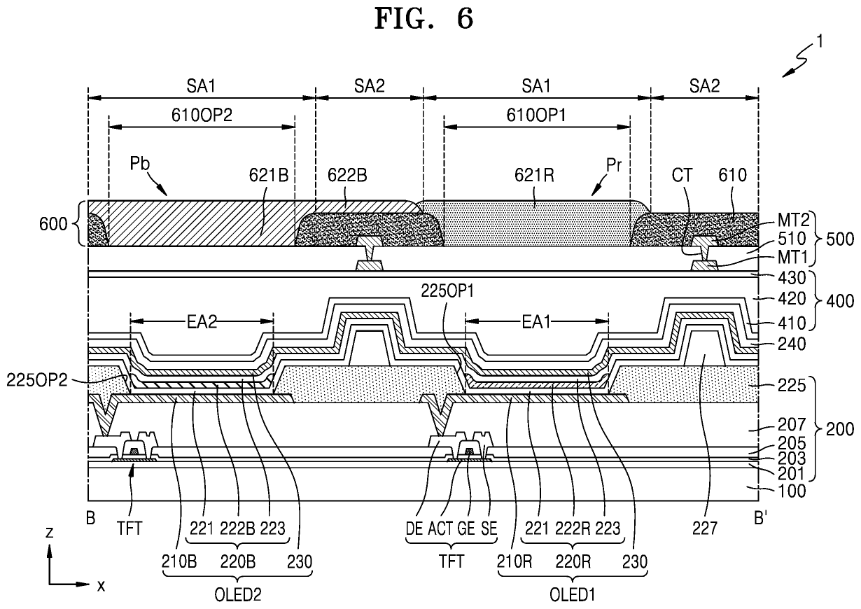

The anti-reflection layer 600 may be disposed over the touch sensor layer 500. The anti-reflection layer 600 may reduce the reflectance of light (external light) incident from the outside toward the display apparatus 1. In an embodiment, the anti-reflection layer 600 may include a light-blocking layer 610 (refer to FIG. 6) and a plurality of color filters 620 (refer to FIG. 6). The configuration of the anti-reflection layer 600 is described below in detail with reference to FIGS. 5 to 7.

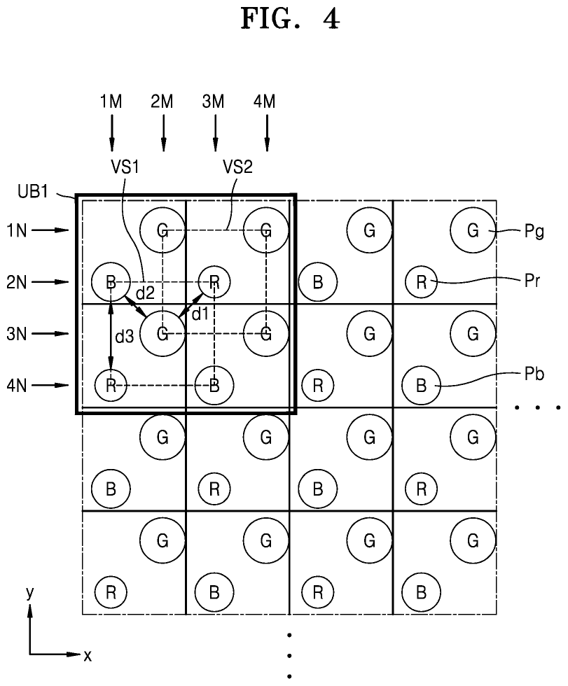

FIG. 4 is a plan view schematically illustrating an embodiment of an arrangement of subpixels of a portion of a display apparatus.

Referring to FIG. 4, a plurality of subpixels P may be arranged in the display area DA of the display apparatus. The plurality of subpixels P may include subpixels P emitting different colors, e.g., a first subpixel of a first color, a second subpixel of a second color, and a third subpixel of a third color. In an embodiment, the first subpixel may be a red subpixel Pr capable of emitting red light, the second subpixel may be a blue subpixel Pb capable of emitting blue light, and the third subpixel may be a green subpixel Pg capable of emitting green light. Hereinafter, it will be assumed that the first subpixel is the red subpixel Pr, the second subpixel is the blue subpixel Pb, and the third subpixel is the green subpixel Pg.

The red subpixel Pr, the blue subpixel Pb, and the green subpixel Pg may be arranged as a Pentile™ type, e.g., a diamond Pentile™ type. Green subpixels Pg may be arranged apart from each other at predetermined intervals in a first row 1N in the first direction (e.g., x direction), red subpixels Pr and blue subpixels Pb may be alternately arranged in a second row 2N adjacent thereto, green subpixels Pg may be arranged apart from each other at predetermined intervals in a third row 3N adjacent thereto, red subpixels Pr and blue subpixels Pb may be alternately arranged in a fourth row 4N adjacent thereto, and the first to fourth rows 1N, 2N, 3N, and 4N may be repeatedly arranged.

The green subpixels Pg arranged in the first row 1N may be alternately arranged with the red subpixels Pr and the blue subpixels Pb arranged in the second row 2N. Thus, red subpixels Pr and blue subpixels Pb may be alternately arranged in a first column 1M, green subpixels Pg may be arranged apart from each other at predetermined intervals in a second column 2M adjacent thereto, red subpixels Pr and blue subpixels Pb may be alternately arranged in a third column 3M adjacent thereto, green subpixels Pg may be arranged apart from each other at predetermined intervals in a fourth column 4M adjacent thereto, and the first to fourth columns 1M, 2M, 3M, and 4M may be repeatedly arranged.

When the arrangement structure of the subpixels P is differently represented, red subpixels Pr and blue subpixels Pb may be arranged at the vertexes of a first virtual square VS1 having a green subpixel Pg as a center point thereof. Red subpixels Pr may be arranged at opposite vertexes with a green subpixel Pg therebetween in a diagonal direction of the first virtual square VS1, and blue subpixels Pb may be arranged at opposite vertexes with the green subpixel Pg therebetween in a diagonal direction of the first virtual square VS1. Green subpixels Pg may be respectively disposed at the vertexes of a second virtual square VS2 having a subpixel (a blue subpixel or a red subpixel) disposed at a vertex of the first virtual square VS1 as a center point thereof. In this case, the first virtual square VS1 and the second virtual square VS2 may be variously modified to have various shapes such as a rectangular shape, a diamond shape, and a square shape. In an embodiment, the first virtual square VS1 and the second virtual square VS2 may have a square shape.

A minimum distance d1 between the red subpixel Pr and the green subpixel Pg and a minimum distance d2 between the blue subpixel Pb and the green subpixel Pg may be less than a minimum distance d3 between the red subpixel Pr and the blue subpixel Pb. The minimum distance d1 between the red subpixel Pr and the green subpixel Pg may be different from the minimum distance d2 between the blue subpixel Pb and the green subpixel Pg, and the minimum distance d1 between the red subpixel Pr and the green subpixel Pg may be less than the minimum distance d2 between the blue subpixel Pb and the green subpixel Pg. In another embodiment, the minimum distance d1 between the red subpixel Pr and the green subpixel Pg may be equal to the minimum distance d2 between the blue subpixel Pb and the green subpixel Pg.

The red subpixel Pr, the blue subpixel Pb, and the green subpixel Pg may have a circular shape. However, the disclosure is not limited thereto. In some embodiments, the red subpixel Pr, the blue subpixel Pb, and the green subpixel Pg may have an elliptical shape or a polygonal shape. The “polygonal shape” may include a shape in which vertexes are rounded.

The sizes (or widths) of the red subpixel Pr, the blue subpixel Pb, and the green subpixel Pg may be different from each other. In an embodiment, the size (or width) of the red subpixel Pr may be less than the sizes (or widths) of the blue subpixel Pb and the green subpixel Pg, for example. The size (or width) of the green subpixel Pg may be greater the size (or width) of the blue subpixel Pb. In other embodiments, the sizes of the red subpixel Pr, the blue subpixel Pb, and the green subpixel Pg may be substantially equal to each other, and various modifications may be made therein.

Herein, the size (or width) of the red subpixel Pr, the blue subpixel Pb, and the green subpixel Pg may refer to the size (or width) of the emission area EA (refer to FIG. 3) of the organic light-emitting diode OLED (refer to FIG. 3) implementing each subpixel P, and the size (or width) of the emission area EA (refer to FIG. 3) may be defined by the size (or width) of the subpixel opening 225OP (refer to FIG. 3) included in the bank layer 225 (refer to FIG. 3).

Referring to FIG. 4, the subpixels P of the display apparatus may include a repetitive arrangement structure of a subpixel pattern unit block UB1. In an embodiment, an arrangement of red subpixels Pr, blue subpixels Pb, and green subpixels Pg may correspond to a repetitive arrangement of a subpixel pattern unit block UB1, for example. The subpixel pattern unit block UB1 may be a virtual unit block having a predetermined area including a red subpixel Pr, a blue subpixel Pb, and a green subpixel Pg and may be understood as corresponding to a minimum repetition unit of the arrangement pattern of the subpixels P included in the display apparatus. In an embodiment, the subpixel pattern unit block UB1 may have a quadrangular (e.g., rectangular) shape. In an embodiment, the subpixel pattern unit block UB1 may have a square shape, for example.

The subpixel pattern unit block UB1 may include red subpixels Pr, blue subpixels Pb, and green subpixels Pg. The sum of the number of red subpixels Pr and the number of blue subpixels Pb included in the subpixel pattern unit block UB1 may be equal to the number of green subpixels Pg included therein. In this regard, FIG. 4 illustrates the subpixel pattern unit block UB1 including two red subpixels Pr, two blue subpixels Pb, and four green subpixels Pg.

FIG. 5 is a plan view illustrating an embodiment of a portion of a display apparatus and illustrating an embodiment of the plurality of color filters 620 that may be disposed over the subpixel pattern unit block UB1 illustrated in FIG. 4.

Referring to FIG. 5, a plurality of color filters 620 may be arranged in the display area DA of the display apparatus. In an embodiment, FIG. 5 illustrates a plurality of color filters 620 corresponding to the subpixel pattern unit block UB1, for example. The plurality of color filters 620 may include a red color filter, a blue color filter, and a green color filter.

The display area DA may include a plurality of first areas SA1 and a plurality of second areas SA2 between the plurality of first areas SA1. The plurality of first areas SA1 may be arranged apart from each other. The first area SA1 may be an area overlapping the subpixel P. Each of the plurality of first areas SA1 may overlap, e.g., the red subpixel Pr, the blue subpixel Pb, or the green subpixel Pg. The first area SA1 may cover the subpixel P, and the size (or width) of the first area SA1 may be greater than the size (or width) of the subpixel P. The first area SA1 may have substantially the same shape as that of the subpixel P corresponding thereto. In an embodiment, FIG. 5 illustrates that the plurality of first areas SA1 has a circular shape in the plan view, for example. However, the disclosure is not limited thereto. In another embodiment, the plurality of first areas SA1 may have a polygonal shape.

The second area SA2 may be disposed between the first areas SA1, and the plurality of second areas SA2 may have the same size. As illustrated in FIG. 5. In an embodiment, the second area SA2 may be an area that is disposed outside the first area SA1 and partitioned by virtual lines connecting the center points of subpixels P adjacent to each other in a diagonal direction oblique to the first direction (e.g., x direction) and the second direction (e.g., y direction), for example. In an embodiment, the second area SA2 may be an area that is disposed outside the first areas SA1 and disposed inside a virtual square VS3 defined by first virtual lines L1 and L1′ connecting the center points of the green subpixel Pg and the blue subpixel Pb adjacent to each other and second virtual lines L2 and L2′ connecting the center points of the red subpixel Pr and the green subpixel Pg adjacent to each other, for example.

The plurality of color filters 620 may include sub color filters. In an embodiment, the plurality of color filters 620 may include a plurality of first sub color filters 621 and a plurality of second sub color filters 622, for example. The plurality of first sub color filters 621 may include a first red sub color filter 621R, a first blue sub color filter 621B, and a first green sub color filter 621G. Each of the plurality of first sub color filters 621 may be arranged in the first area SA1 overlapping the subpixel P of the same color among the plurality of first areas SA1. In an embodiment, the first red sub color filter 621R may be disposed in the first area SA1 where the red subpixel Pr is disposed, and the first blue sub color filter 621B may be disposed in the first area SA1 where the blue subpixel Pb is disposed, and the first green sub color filter 621G may be disposed in the first area SA1 where the green subpixel Pg is disposed, for example. The plurality of first sub color filters 621 may be arranged apart from each other.

In the plan view, the size (or width) of the first sub color filter 621 may be substantially equal to the size (or width) of the first area SA1 corresponding thereto. The size (or width) of the first sub color filter 621 may be greater than the size (or width) of the subpixel P corresponding thereto. The first sub color filter 621 may have substantially the same shape as that of the subpixel P corresponding thereto. In an embodiment, the first sub color filters 621 may have a circular shape in the plan view, for example. However, the disclosure is not limited thereto. In another embodiment, the first sub color filters 621 may have a polygonal shape.

In an embodiment, the size (or width) of the first red sub color filter 621R may be greater than the size (or width) of the red subpixel Pr, for example. The size (or width) of the first blue sub color filter 621B may be greater than the size (or width) of the blue subpixel Pb. The size (or width) of the first green sub color filter 621G may be greater than the size (or width) of the green subpixel Pg. In an embodiment, the first red sub color filter 621R, the first blue sub color filter 621B, and the first green sub color filter 621G may have a circular shape in the plan view.

The sizes (or widths) of the first red sub color filter 621R, the first blue sub color filter 621B, and the first green sub color filter 621G may be different from each other. In an embodiment, the size (or width) of the first red sub color filter 621R may be less than the size (or width) of the first blue sub color filter 621B and the size (or width) of the first green sub color filter 621G, for example. Also, the size (or width) of the first green sub color filter 621G may be greater than the size (or width) of the first blue sub color filter 621B. In other embodiments, the size (or width) of the first green sub color filter 621G may be less than the size (or width) of the first blue sub color filter 621B, or the sizes (or widths) of the first red sub color filter 621R, the first blue sub color filter 621B, and the first green sub color filter 621G may be substantially equal to each other, and various modifications may be made therein.

The plurality of second sub color filters 622 may include a second red sub color filter 622R, a second blue sub color filter 622B, and a second green sub color filter 622G. Each of the plurality of second sub color filters 622 may be arranged in one of the plurality of second areas SA2. Each of the second areas SA2 may be arranged outside the first areas SA1 and may surround at least a portion of the first area SA1 adjacent thereto. Thus, each of the second sub color filters 622 arranged in the second area SA2 may at least partially surround the first sub color filter 621 disposed in the first area SA1 adjacent thereto. FIG. 5 illustrates that four second areas SA2 are disposed at the vertexes of a virtual square VS4 centered on one first green sub color filter 621G, and the second blue sub color filter 622B, the second red sub color filter 622R, and the second green sub color filter 622G are arranged in three second areas SA2 among the four second areas SA2.

One of the second red sub color filter 622R, the second blue sub color filter 622B, and the second green sub color filter 622G may be arranged in each of the plurality of second areas SA2. However, in some embodiments, the second sub color filter 622 may not be disposed in at least one of the plurality of second areas SA2. As described below with reference to FIG. 6, the upper surface of the light-blocking layer 610 may be exposed by the second area SA2 where no color filter is disposed.

In this regard, FIG. 5 illustrates eight first areas SA1 and eight second areas SA2 and that the second red sub color filter 622R is disposed in two second areas SA2 among the second areas SA2, the second blue sub color filter 622B is disposed in one second area SA2, the second green sub color filter 622G is disposed in three second areas SA2, and no color filter is disposed in the other two second areas SA2.

By embodiments, first sub color filters 621 having the color corresponding to each subpixel P may be arranged in the first areas SA1, and one of the second red sub color filter 622R, the second blue sub color filter 622B, and the second green sub color filter 622G may be disposed or the color filter 620 may not be disposed in each of the second areas SA2 having the same size. Thus, according to the disclosure, the overall area ratio of the red color filter, the blue color filter, and the green color filter may be easily adjusted by adjusting the number of second red sub color filters 622R, second blue sub color filters 622B, and second green sub color filters 622G arranged in the second area SA2. The area ratio of the red color filter, the blue color filter, and the green color filter may affect the reflection color of the display apparatus, and it may be easy to change the design of the color filter for adjusting the reflection color. Also, it may be easy to change the mask according to the design of the color filter.

Also, because color filters 620 of several colors are not arranged in each of the second areas SA2 but a color filter 620 of one color or no color filter 620 is disposed therein, it may be easy to predict the color of the entirety of the panel according to the change in the color of each second area SA2.

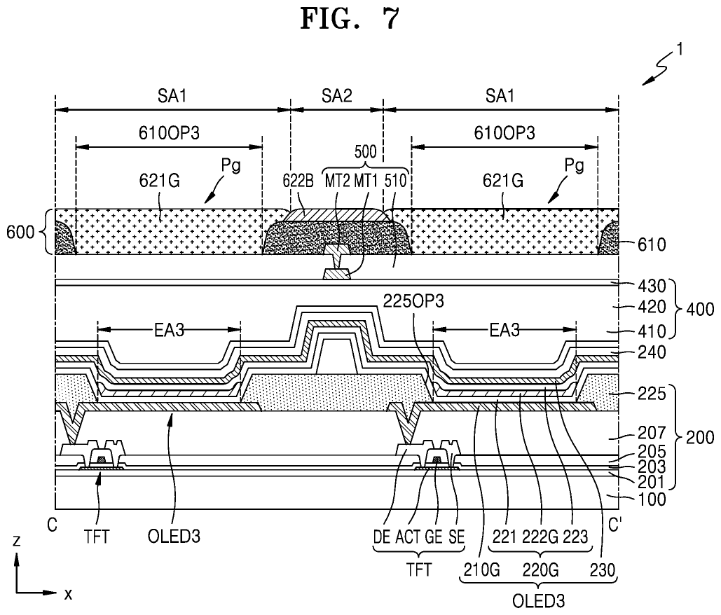

FIGS. 6 and 7 are cross-sectional views schematically illustrating an embodiment of a portion of a display apparatus. FIG. 6 is a cross-sectional view of the display apparatus taken along line B-B′ of FIG. 5, and FIG. 7 is a cross-sectional view of the display apparatus taken along line C-C′ of FIG. 5.

Referring to FIGS. 6 and 7, in the display apparatus 1, a substrate 100, a display layer 200, an encapsulation layer 400, a touch sensor layer 500, and an anti-reflection layer 600 may be sequentially stacked. Because the detailed structure of the display apparatus 1 is the same as that described above with reference to FIG. 3, redundant descriptions thereof are omitted for conciseness.

The display layer 200 may be disposed over the substrate 100. The display layer 200 may include a subpixel circuit layer and a light-emitting diode layer. The subpixel circuit layer may include a thin film transistor TFT and may include a buffer layer 201, a gate insulating layer 203, an inter-insulating layer 205, and a planarization layer 207 that are insulating layers.

The light-emitting diode layer may include a light-emitting diode. The light-emitting diode layer may include a bank layer 225, a spacer 227, and an organic light-emitting diode OLED. FIG. 6 illustrates a first organic light-emitting diode OLED1 corresponding to the red subpixel Pr and a second organic light-emitting diode OLED2 corresponding to the blue subpixel Pb, and FIG. 7 illustrates third organic light-emitting diodes OLED3 corresponding to the green subpixels Pg.

The first organic light-emitting diode OLED1 may include a stack structure of a first subpixel electrode 210R, a first intermediate layer 220R including a first common layer 221, a first emission layer 222R, and a second common layer 223, and an opposite electrode 230, the second organic light-emitting diode OLED2 may include a second subpixel electrode 210B, a second intermediate layer 220B including a first common layer 221, a second emission layer 222B, and a second common layer 223, and an opposite electrode 230, and the third organic light-emitting diode OLED3 may include a third subpixel electrode 210G, a third intermediate layer 220G including a first common layer 221, a third emission layer 222G, and a second common layer 223, and an opposite electrode 230.

The bank layer 225 may include a light-blocking material. A first subpixel opening 225OP1 exposing at least a portion of the first subpixel electrode 210R, a second subpixel opening 225OP2 exposing at least a portion of the second subpixel electrode 210B, and a third subpixel opening 225OP3 exposing at least a portion of the third subpixel electrode 210G may be defined in the bank layer 225.

The first subpixel opening 225OP1 of the bank layer 225 may define the first emission area EA1 of the first organic light-emitting diode OLED1 included in the red subpixel Pr. The second subpixel opening 225OP2 of the bank layer 225 may define the second emission area EA2 of the second organic light-emitting diode OLED2 included in the blue subpixel Pb. The third subpixel opening 225OP3 may define the third emission area EA3 of the third organic light-emitting diode OLED3 included in the green subpixel Pg.

A capping layer 240 may cover the opposite electrode 230. The encapsulation layer 400 may be disposed over the capping layer 240. The encapsulation layer 400 may include a first inorganic encapsulation layer 410, a second inorganic encapsulation layer 430, and an organic encapsulation layer 420 between the first inorganic encapsulation layer 410 and the second inorganic encapsulation layer 430.

The touch sensor layer 500 may be disposed over the encapsulation layer 400. The touch sensor layer 500 may include a first touch electrode MT1, a first touch insulating layer 510, and a second touch electrode MT2. The second touch electrode MT2 may be electrically connected to the first touch electrode MT1 through a contact hole CT defined in the first touch insulating layer 510.

The first touch electrode MT1 and/or the second touch electrode MT2 of the touch sensor layer 500 may overlap a body portion of the bank layer 225 disposed between the emission areas EA of the organic light-emitting diode OLED. In an embodiment, the first touch electrode MT1 and the second touch electrode MT2 may overlap a portion of the bank layer 225 between the first emission area EA1 of the first organic light-emitting diode OLED1 and the second emission area EA2 of the second organic light-emitting diode OLED2, for example.

Referring to FIGS. 6 and 7, the anti-reflection layer 600 may be disposed over the touch sensor layer 500. The anti-reflection layer 600 may include a light-blocking layer 610 and a plurality of color filters 620 (refer to FIG. 5).

The light-blocking layer 610 may be disposed over the touch sensor layer 500. In an embodiment, the light-blocking layer 610 may directly contact at least one of the touch electrodes of the touch sensor layer 500, e.g., the second touch electrode MT2. A body portion of the light-blocking layer 610 may overlap the first touch electrode MT1 and/or the second touch electrode MT2 of the touch sensor layer 500.

First to third openings 610OP1, 610OP2, and 610OP3 respectively corresponding to the first to third emission areas EA1, EA2, and EA3 may be defined in the light-blocking layer 610. The first to third openings 610OP1, 610OP2, and 610OP3 may be an area defined by removing a portion of the light-blocking layer 610, through which light emitted from the organic light-emitting diode may be emitted to the outside. The body portion of the light-blocking layer 610 may include a material absorbing external light. Accordingly, the visibility of the display apparatus 1 may be improved.

As described above, the first to third emission areas EA1, EA2, and EA3 may be respectively defined by the first to third subpixel openings 225OP1, 225OP2, and 225OP3 of the bank layer 225, and the first to third openings 610OP1, 610OP2, and 610OP3 of the light-blocking layer 610 may respectively overlap the first to third subpixel openings 225OP1, 225OP2, and 225OP3 of the bank layer 225. The first to third openings 610OP1, 610OP2, and 610OP3 may respectively correspond to the first to third emission areas EA1, EA2, and EA3 of the first to third organic light-emitting diodes OLED1, OLED2, and OLED3. The first opening 610OP1 of the light-blocking layer 610 may overlap the first subpixel opening 225OP1 of the bank layer 225, the second opening 610OP2 may overlap the second subpixel opening 225OP2, and the third opening 610OP3 may overlap the third subpixel opening 225OP3.

The size (or width) of each of the first to third openings 610OP1, 610OP2, and 610OP3 of the light-blocking layer 610 may be greater than the size (or width) of each of the first to third subpixel openings 225OP1, 225OP2, and 225OP3 of the bank layer 225 corresponding thereto. When the light-blocking layer 610 and the bank layer 225 have an inclination in the side surface, the size (or width) of each opening included in the light-blocking layer 610 and the bank layer 225 may vary depending on the thickness direction. The size (or width) of the opening herein may refer to “the minimum size (or width)”.

In an embodiment, the size (or width) of the first opening 610OP1 may be greater than the size (or width) of the first subpixel opening 225OP1, for example. Also, the size (or width) of the second opening 610OP2 may be greater than the size (or width) of the second subpixel opening 225OP2, and the size (or width) of the third opening 610OP3 may be greater than the size (or width) of the third subpixel opening 225OP3. However, the disclosure is not limited thereto, and in another embodiment, the size (or width) of each of the first to third openings 610OP1, 610OP2, and 610OP3 of the light-blocking layer 610 may be substantially equal to the size (or width) of each of the first to third subpixel openings 225OP1, 225OP2, and 225OP3 of the bank layer 225 corresponding thereto.

The plurality of color filters 620 may be disposed over the light-blocking layer 610. As described above with reference to FIG. 5, the plurality of color filters 620 may include a plurality of first sub color filters 621 and a plurality of second sub color filters 622. The first sub color filters 621 may include a first red sub color filter 621R, a first blue sub color filter 621B, and a first green sub color filter 621G, and the second sub color filters 622 may include a second red sub color filter 622R, a second blue sub color filter 622B, and a second green sub color filter 622G.

Each of the first areas SA1 in which the first sub color filters 621 are arranged may overlap the emission area EA of the subpixel P, e.g., one of the first emission area EA1 of the red subpixel Pr, the second emission area EA2 of the blue subpixel Pb, and the third emission area EA3 of the green subpixel Pg. In an embodiment, the first red sub color filter 621R may overlap the first emission area EA1, for example. The first blue sub color filter 621B may overlap the second emission area EA2. The first green sub color filter 621G may overlap the third emission area EA3.

The first sub color filters 621 may fill at least a portion of the openings of the light-blocking layer 610. In an embodiment, the first red sub color filter 621R may fill the first opening 610OP1 of the light-blocking layer 610, for example. The first blue sub color filter 621B may fill the second opening 610OP2 of the light-blocking layer 610. The first green sub color filter 621G may fill the third opening 610OP3 of the light-blocking layer 610.

The size (or width) of the first red sub color filter 621R may be greater than the size (or width) of the first opening 610OP1 of the light-blocking layer 610. The size (or width) of the first blue sub color filter 621B may be greater than the size (or width) of the second opening 610OP2 of the light-blocking layer 610. The size (or width) of the first green sub color filter 621G may be greater than the size (or width) of the third opening 610OP3 of the light-blocking layer 610. In an embodiment, the size (or width) of the first sub color filter 621 may be designed as a minimum size (or width) capable of entirely covering the opening of the light-blocking layer 610 corresponding thereto.

The second areas SA2 in which the second sub color filters 622 are arranged may overlap the light-blocking layer 610. The second sub color filters 622 may be arranged between the first sub color filters 621 to cover the upper surface of the light-blocking layer 610. The upper surface of the light-blocking layer 610 may be exposed by the second area SA2 in which the second sub color filter 622 is not disposed.

In an embodiment, the first sub color filter 621 and the second sub color filter 622 adjacent to each other may contact or overlap each other over the light-blocking layer 610. In this case, when the first sub color filter 621 and the second sub color filter 622 adjacent to each other have the same color, the first sub color filter 621 and the second sub color filter 622 may be unitary.

In an embodiment, FIG. 6 illustrates that the second blue sub color filter 622B is disposed in the second area SA2 disposed between the first blue sub color filter 621B and the first red sub color filter 621R, and the second sub color filter 622 is not disposed in the other second area SA2 disposed on one side of the second red sub color filter 622R, for example. In this case, the first blue sub color filter 621B and the second blue sub color filter 622B adjacent to each other may be unitary. Also, the second blue sub color filter 622B and the first red sub color filter 621R adjacent to each other may contact each other over the light-blocking layer 610. The upper surface of the light-blocking layer 610 may be exposed by the second area SA2 in which the second sub color filter 622 is not disposed.

In an embodiment, FIG. 7 illustrates that the second blue sub color filter 622B is disposed in the second area SA2 disposed between two first green sub color filters 621G, for example. The first green sub color filter 621G and the second blue sub color filter 622B adjacent to each other may contact each other over the light-blocking layer 610.

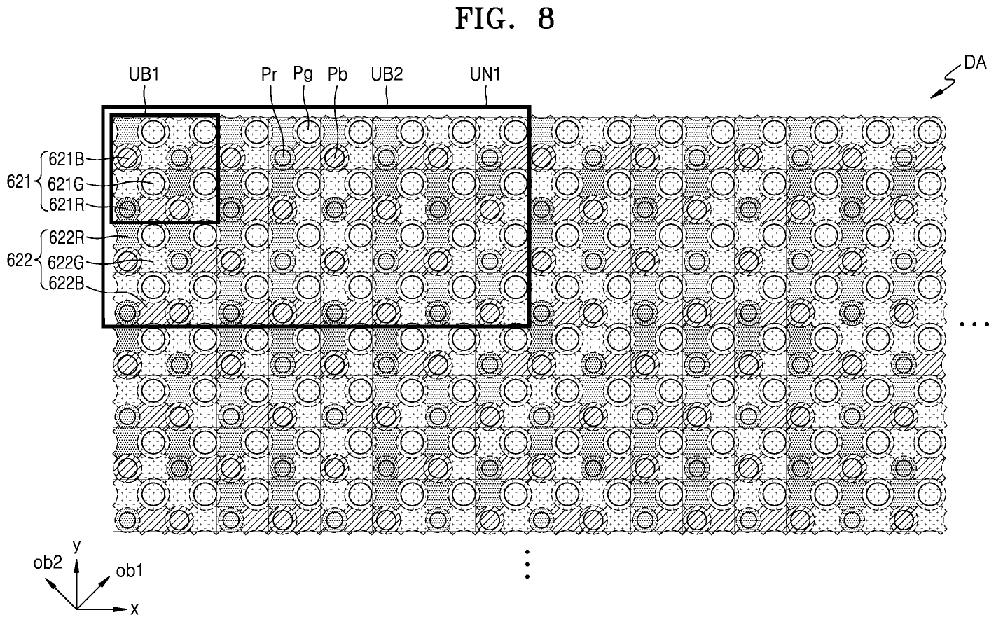

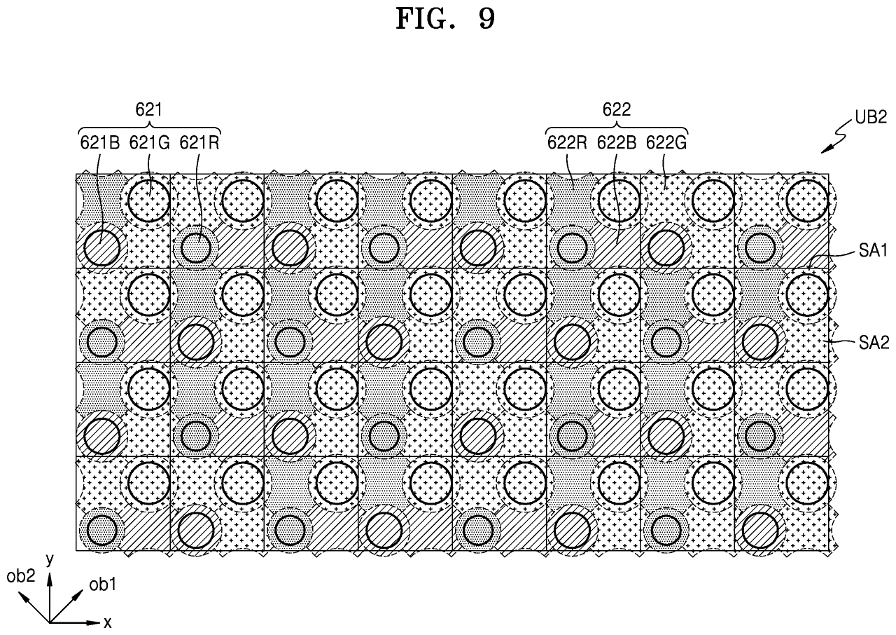

FIG. 8 is a plan view illustrating an embodiment of a portion of a display apparatus, and FIG. 9 is a plan view illustrating a color filter pattern unit block in FIG. 8.

Referring to FIGS. 8 and 9, a plurality of color filters 620 (refer to FIG. 5) arranged in the display area DA of the display apparatus may include a first color filter pattern unit UN1. The first color filter pattern unit UN1 may be a virtual unit having a predetermined area including a red color filter, a blue color filter, and a green color filter and may correspond to a unit disposed in a minimum number of first areas SA1 and second areas SA2 desired for adjusting the reflection color. In an embodiment, FIG. 8 illustrates that the first color filter pattern unit UN1 is disposed in 64 first areas SA1 and 64 second areas SA2, for example. The first color filter pattern unit UN1 may include 64 first sub color filters 621 respectively arranged in 64 first areas SA1 and 64 second sub color filters 622 respectively arranged in 64 second areas SA2. In an embodiment, the first color filter pattern unit UN1 may include 22 second red sub color filters 622R, 15 second blue sub color filters 622B, and 27 second green sub color filters 622G, for example.

The size of the first color filter pattern unit UN1 may be greater than the size of the subpixel pattern unit block UB1. The subpixels P corresponding to the first color filter pattern unit UN1 may have a repetitive arrangement structure of the subpixel pattern unit block UB1. An arrangement of the subpixels P corresponding to the first color filter pattern unit UN1 may correspond to a repetitive arrangement of the subpixel pattern unit block UB1.

The subpixels P corresponding to the first color filter pattern unit UN1 may have a structure in which A (A is a natural number) subpixel pattern unit blocks UB1 are arranged in the first direction (e.g., x direction) and B (B is a natural number) subpixel pattern unit blocks UB1 are arranged in the second direction (e.g., y direction) orthogonal to the first direction. In other words, the arrangement of the subpixels P corresponding to the first color filter pattern unit UN1 may correspond to the arrangement pattern of the subpixels P when subpixel pattern unit blocks UB1 are arranged in an array of A×B (A and B are natural numbers). FIG. 8 illustrates that the first color filter pattern unit UN1 corresponds to a 4×2 array of subpixel pattern unit blocks UB1.

The first color filter pattern unit UN1 may include a first sub color filter pattern in which first sub color filters 621 are arranged and a second sub color filter pattern in which second sub color filters 622 are arranged.

In an embodiment, the second sub color filter pattern of the first color filter pattern unit UN1 may include an arrangement of second sub color filters 622 of two or more colors in at least one of the first direction (e.g., x direction) and the second direction (e.g., y direction) orthogonal to the first direction. In this regard, FIG. 8 illustrates that the second sub color filter pattern of the first color filter pattern unit UN1 includes an arrangement of second sub color filters 622 of two or more colors in the first direction (e.g., x direction).

In an embodiment, the second sub color filter pattern of the first color filter pattern unit UN1 may include an arrangement of second sub color filters 622 of two or more colors in at least one of a first diagonal direction (e.g., ob1 direction) having an acute angle with respect to the first direction (e.g., x direction) and the second direction (e.g., y direction) orthogonal to the first direction and a second diagonal direction (e.g., ob2 direction) intersecting the first diagonal direction (e.g., ob1 direction). In this regard, FIG. 8 illustrates that the second sub color filter pattern of the first color filter pattern unit UN1 includes an arrangement of second sub color filters 622 of two or more colors two or more colors in the first diagonal direction (e.g., ob1 direction) and the second diagonal direction (e.g., ob2 direction).

A plurality of color filters 620 arranged in the display area DA of the display apparatus may include a repetitive arrangement structure of a color filter pattern unit block UB2. In an embodiment, an arrangement of red color filters, blue color filters, and green color filters may correspond to a repetitive arrangement of the color filter pattern unit block UB2, for example. The color filter pattern unit block UB2 may be a virtual unit block having a predetermined area including a red color filter, a blue color filter, and a green color filter and may be understood as corresponding to a minimum repetition unit of the arrangement pattern of the color filters 620 included in the display apparatus.

In an embodiment, the color filter pattern unit block UB2 may have the same size as that of the first color filter pattern unit UN1. In this case, the arrangement of the color filters 620 of the first color filter pattern unit UN1 may be the same as the arrangement of the color filters 620 of the color filter pattern unit block UB2. That is, the first color filter pattern unit UN1 may correspond to a minimum repetition unit of the arrangement pattern of the color filters 620 included in the display apparatus.

The color filter pattern unit block UB2 may have a greater size than that of the subpixel pattern unit block UB1. The subpixels P corresponding to the color filter pattern unit block UB2 may have a repetitive arrangement structure of the subpixel pattern unit block UB1. An arrangement of the subpixels P corresponding to the color filter pattern unit block UB2 may correspond to a repetitive arrangement of the subpixel pattern unit block UB1.

The subpixels P corresponding to the color filter pattern unit block UB2 may have a structure in which K (K is a natural number) subpixel pattern unit blocks UB1 are arranged in the first direction (e.g., x direction) and L (L is a natural number) subpixel pattern unit blocks UB1 are arranged in the second direction (e.g., y direction) orthogonal to the first direction. In other words, the arrangement of the subpixels P corresponding to the color filter pattern unit block UB2 may correspond to the arrangement pattern of the subpixels P when subpixel pattern unit blocks UB1 are arranged in an array of K×L (K and L are natural numbers). FIGS. 8 and 9 illustrate that each color filter pattern unit block UB2 corresponds to a 4×2 array of subpixel pattern unit blocks UB1, like the first color filter pattern unit UN1.

The color filter pattern unit block UB2 may include a first sub color filter pattern in which first sub color filters 621 are arranged and a second sub color filter pattern in which second sub color filters 622 are arranged.

In an embodiment, the second sub color filter pattern of the color filter pattern unit block UB2 may include an arrangement of second sub color filters 622 of two or more colors in at least one of the first direction (e.g., x direction) and the second direction (e.g., y direction).

In an embodiment, the second sub color filter pattern of the color filter pattern unit block UB2 may include an arrangement of second sub color filters 622 of two or more colors in at least one of the first diagonal direction (e.g., ob1 direction) and the second diagonal direction (e.g., ob2 direction).

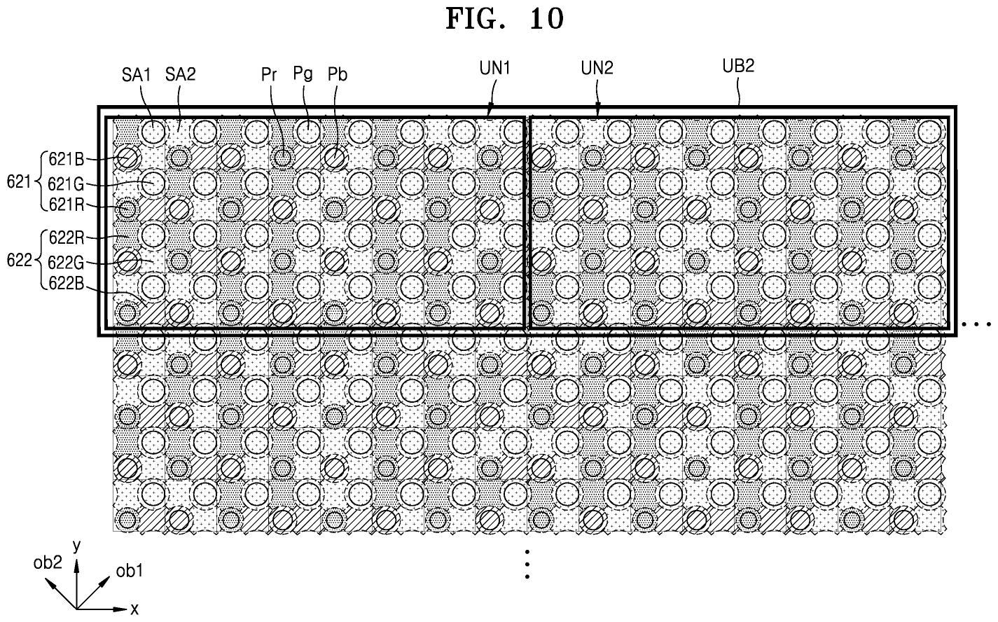

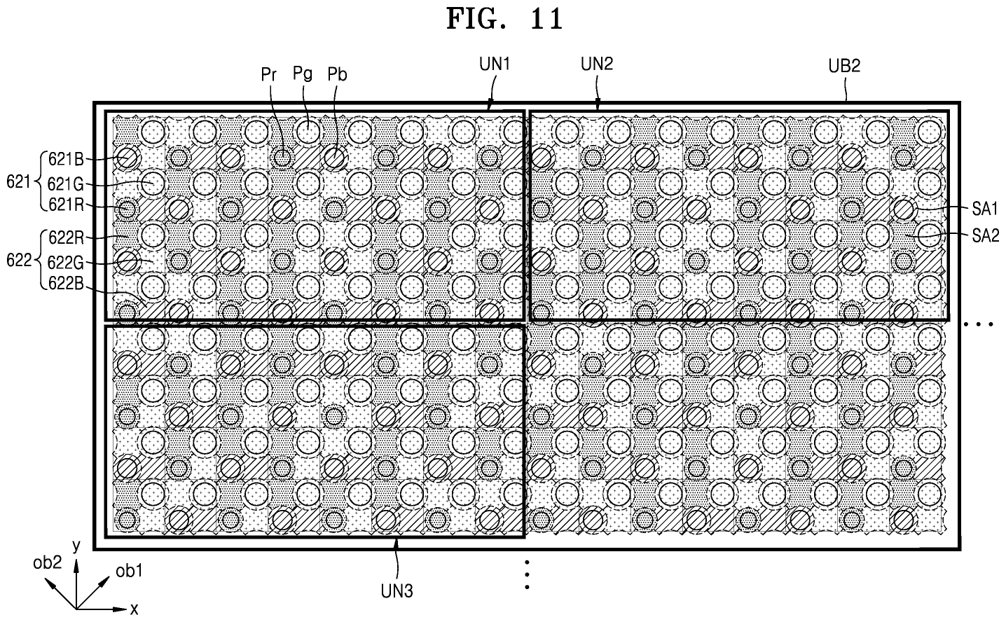

FIGS. 10 and 11 are plan views illustrating other embodiments of a portion of a display apparatus. Because the embodiments of FIGS. 10 and 11 are different from the embodiment of FIG. 8 in the configuration of the color filter pattern unit block UB2, hereinafter, the differences in the color filter pattern unit block UB2 will be mainly described and redundant descriptions thereof are omitted for conciseness.

Referring to FIGS. 10 and 11, the color filter pattern unit block UB2 may have a greater size than that of the first color filter pattern unit UN1. In this case, the color filter pattern unit block UB2 may include one or more other color filter pattern units having the same size as that of the first color filter pattern unit UN1. The arrangement of the color filters 620 of the other color filter pattern unit may be different from the arrangement of the color filters 620 of the first color filter pattern unit UN1.

In this regard, FIG. 10 illustrates that the color filter pattern unit block UB2 includes one first color filter pattern unit UN1 and one second color filter pattern unit UN2, and FIG. 11 illustrates that the color filter pattern unit block UB2 includes two first color filter pattern units UN1, one second color filter pattern unit UN2, and one third color filter pattern unit UN3.

Each of the second color filter pattern unit UN2 and the third color filter pattern unit UN3 may be a virtual unit having a predetermined area including a red color filter, a blue color filter, and a green color filter and may correspond to a unit disposed in a minimum number of first areas SA1 and second areas SA2 desired for adjusting the reflection color. FIGS. 10 and 11 illustrate that, like the first color filter pattern unit UN1, the second and third color filter pattern units UN2 and UN3 are arranged in 64 first areas SA1 and 64 second areas SA2. The second and third color filter pattern units UN2 and UN3 may include 64 first sub color filters 621 respectively arranged in 64 first areas SA1 and 64 second sub color filters 622 respectively arranged in 64 second areas SA2.

The second color filter pattern unit UN2 and the third color filter pattern unit UN3 may have the same size as that of the first color filter pattern unit UN1. The subpixels P corresponding to the second color filter pattern unit UN2 and the third color filter pattern unit UN3 may have a repetitive arrangement structure of the subpixel pattern unit block UB1. In an embodiment, each of the second and third color filter pattern units UN2 and UN3 may correspond to a 4×2 array of subpixel pattern unit blocks UB1, for example.

Each of the second color filter pattern unit UN2 and the third color filter pattern unit UN3 may include a first sub color filter pattern in which first sub color filters 621 are arranged and a second sub color filter pattern in which second sub color filters 622 are arranged.

The second color filter pattern unit UN2 and the third color filter pattern unit UN3 may have an arrangement of color filters 620 different from the arrangement of the color filters 620 included in the first color filter pattern unit UN1. Also, the second color filter pattern unit UN2 may have an arrangement of color filters 620 different from the arrangement of the color filters 620 included in the third color filter pattern unit UN3. Particularly, the second sub color filter pattern of the second color filter pattern unit UN2 may be different from the second sub color filter pattern of the first color filter pattern unit UN1. The second sub color filter pattern of the third color filter pattern unit UN3 may be different from the second sub color filter pattern of the first color filter pattern unit UN1. Also, the second sub color filter pattern of the second color filter pattern unit UN2 may be different from the second sub color filter pattern of the third color filter pattern unit UN3.

The number of second red sub color filters 622R included in each of the second color filter pattern unit UN2 and the third color filter pattern unit UN3 may be equal to the number of second red sub color filters 622R included in the first color filter pattern unit UN1. The number of second blue sub color filters 622B included in each of the second color filter pattern unit UN2 and the third color filter pattern unit UN3 may be equal to the number of second blue sub color filters 622B included in the first color filter pattern unit UN1. The number of second green sub color filters 622G included in each of the second color filter pattern unit UN2 and the third color filter pattern unit UN3 may be equal to the number of second green sub color filters 622G included in the first color filter pattern unit UN1. In an embodiment, FIGS. 10 and 11 illustrate that, like the first color filter pattern unit UN1, the second color filter pattern unit UN2 and the third color filter pattern unit UN3 include 22 second red sub color filters 622R, 15 second blue sub color filters 622B, and 27 second green sub color filters 622G, for example.

In an embodiment, the second sub color filter pattern of each of the second color filter pattern unit UN2 and the third color filter pattern unit UN3 may include an arrangement of second sub color filters 622 of two or more colors in at least one of the first direction (e.g., x direction) and the second direction (e.g., y direction). In this regard, FIGS. 10 and 11 illustrate that the second sub color filter pattern of the second color filter pattern unit UN2 and the third color filter pattern unit UN3 includes an arrangement of second sub color filters 622 of two or more colors in the first direction (e.g., x direction).

In an embodiment, the second sub color filter pattern of each of the second color filter pattern unit UN2 and the third color filter pattern unit UN3 may include an arrangement of second sub color filters 622 of two or more colors in at least one of the first diagonal direction (e.g., ob1 direction) and the second diagonal direction (e.g., ob2 direction). In this regard, FIGS. 10 and 11 illustrate that the second sub color filter pattern of the second color filter pattern unit UN2 and the third color filter pattern unit UN3 includes an arrangement of second sub color filters 622 of two or more colors in the first diagonal direction (e.g., ob1 direction) and the second diagonal direction (e.g., ob2 direction).

The color filter pattern unit block UB2 may have a greater size than that of the first color filter pattern unit UN1. The subpixels P corresponding to the color filter pattern unit block UB2 may have a structure in which the subpixels P corresponding to the first color filter pattern unit UN1 are repeatedly arranged.

The subpixels P corresponding to the color filter pattern unit block UB2 may have a structure in which M (M is a natural number) subpixels P corresponding to the first color filter pattern unit UN1 are arranged in the first direction (e.g., x direction) and N (N is a natural number) subpixels P corresponding thereto are arranged in the second direction (e.g., y direction). In an embodiment, when the first color filter pattern unit UN1 corresponds to a 4×2 array of subpixel pattern unit blocks UB1, the color filter pattern unit block UB2 illustrated in FIG. 10 may correspond to an 8×2 array of subpixel pattern unit blocks UB1, for example. The color filter pattern unit block UB2 illustrated in FIG. 11 may correspond to a 16×4 array of subpixel pattern unit blocks UB1.

By the embodiments described above, a display apparatus in which the design of the color filter for adjusting the reflection color is easily modified may be provided. However, the scope of the disclosure is not limited to these effects.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display apparatus comprising:
a substrate;
a plurality of subpixels including a red subpixel, a blue subpixel, and a green subpixel, each of the red subpixel, the blue subpixel and the green subpixel including:
a subpixel electrode;
an emission layer over the subpixel electrode; and
an opposite electrode over the emission layer;
an encapsulation layer over the plurality of subpixels;
a light-blocking layer disposed over the encapsulation layer and including a plurality of openings respectively overlapping the plurality of subpixels; and
a plurality of color filters disposed over the light-blocking layer and including a red color filter, a blue color filter, and a green color filter,
wherein the plurality of color filters includes a repetitive arrangement structure of a color filter pattern unit block including the red color filter, the blue color filter, and the green color filter,
the plurality of subpixels includes a repetitive arrangement structure of a subpixel pattern unit block including the red subpixel, the blue subpixel, and the green subpixel, and
a size of the color filter pattern unit block is greater than a size of the subpixel pattern unit block.

2. The display apparatus of claim 1, wherein, each of the red subpixel, the green subpixel and the blue subpixel is provided in plural, and
in the subpixel pattern unit block, a number of green subpixels is equal to a sum of a number of red subpixels and a number of blue subpixels.

3. The display apparatus of claim 1, wherein the plurality of subpixels is arranged in a Pentile structure.

4. The display apparatus of claim 1, wherein subpixels of the plurality of subpixels corresponding to the color filter pattern unit block have a structure in which K (K is a natural number) subpixel pattern unit blocks are arranged in a first direction and L (L is a natural number) subpixel pattern unit blocks are arranged in a second direction orthogonal to the first direction.

5. The display apparatus of claim 1, wherein the plurality of color filters includes:
a plurality of first sub color filters respectively arranged in a plurality of first areas, filling at least a portion of openings of the light-blocking layer, and including a first red sub color filter, a first blue sub color filter, and a first green sub color filter; and
a plurality of second sub color filters respectively arranged in a plurality of second areas between the plurality of first areas, covering an upper surface of the light-blocking layer, and including a second red sub color filter, a second blue sub color filter, and a second green sub color filter.

6. The display apparatus of claim 5, wherein the plurality of second areas has a same size.

7. The display apparatus of claim 5, wherein a color filter of the plurality of color filters is not disposed in at least one of the plurality of second areas.

8. The display apparatus of claim 5, wherein, among the plurality of first sub color filters and the plurality of second sub color filters, color filters contacting each other and having a same color are unitary with each other.

9. The display apparatus of claim 5, wherein the color filter pattern unit block includes a first sub color filter pattern in which the plurality of first sub color filters is arranged and a second sub color filter pattern in which the plurality of second sub color filters is arranged.

10. The display apparatus of claim 9, wherein, in the second sub color filter pattern, second sub color filters of two or more colors among the plurality of the second sub color filters are arranged in at least one of a first direction and a second direction orthogonal to the first direction.

11. The display apparatus of claim 9, wherein, in the second sub color filter pattern, second sub color filters of two or more colors among the plurality of the second sub color filters are arranged in a diagonal direction oblique to a first direction and a second direction orthogonal to the first direction.

12. The display apparatus of claim 5, wherein a size of the first red sub color filter is less than a size of the first blue sub color filter and a size of the first green sub color filter.

13. The display apparatus of claim 5, wherein the plurality of first sub color filters has a circular shape in a plan view.

14. The display apparatus of claim 5, wherein a first sub color filter of the plurality of first sub color filters and a second sub color filter of the plurality of second sub color filters adjacent to each other contact or overlap each other over the light-blocking layer.

15. The display apparatus of claim 5, wherein the plurality of color filters includes a first color filter pattern unit including the red color filter, the blue color filter, and the green color filter, and
the color filter pattern unit block has a same size as or a greater size than a size of the first color filter pattern unit.

16. The display apparatus of claim 15, wherein the color filter pattern unit block includes the first color filter pattern unit and a second color filter pattern unit adjacent to the first color filter pattern unit and including the red color filter, the blue color filter, and the green color filter, and
each of the first color filter pattern unit and the second color filter pattern unit includes first sub color filters of the plurality of first sub color filters and second sub color filters of the plurality of second sub color filters,
wherein an arrangement of the second sub color filters of the second color filter pattern unit is different from an arrangement of the second sub color filters of the first color filter pattern unit.

17. The display apparatus of claim 16, wherein a number of second red sub color filters included in the second color filter pattern unit is equal to a number of second red sub color filters included in the first color filter pattern unit,
a number of second blue sub color filters included in the second color filter pattern unit is equal to a number of second blue sub color filters included in the first color filter pattern unit, and
a number of second green sub color filters included in the second color filter pattern unit is equal to a number of second green sub color filters included in the first color filter pattern unit.

18. The display apparatus of claim 1, further comprising:
a bank layer in which a plurality of subpixel openings exposing at least a portion of each of the subpixel electrodes is defined; and
a touch sensor layer including touch electrodes arranged between the encapsulation layer and the light-blocking layer,
wherein the touch electrodes overlap the bank layer and some of the plurality of color filters.

19. The display apparatus of claim 18, wherein at least one of the touch electrodes directly contacts the light-blocking layer.

20. The display apparatus of claim 18, wherein the bank layer includes a light-blocking material.
